(19) United States
(12) Patent Application Publication
(10) Pub. No.: US 2025/0331311 A1
(43) Pub. Date: Oct. 23, 2025

(54) ELECTROSTATIC DISCHARGE SEMICONDUCTOR DEVICE AND MANUFACTURING METHOD THEREOF

(71) Applicant: Joulwatt Technology Co., Ltd., Hangzhou (CN)

(72) Inventor: Zhiqin DENG, Hangzhou (CN)

(21) Appl. No.: 19/176,531

(22) Filed: Apr. 11, 2025

(30) Foreign Application Priority Data
Apr. 17, 2024 (CN) 202410461669.4

(51) Int. Cl. H10D 89/60; H10D 10/00; H10D 10/01; H10D 10/60; H10D 62/10; H10D 62/60; H10D 84/01; H10D 84/60

(52) U.S. Cl. CPC H10D 89/713; H10D 10/241; H10D 10/60; H10D 62/108; H10D 62/124; H10D 62/60; H10D 84/645; H10D 10/061; H10D 84/0112

(57) ABSTRACT

An electrostatic discharge semiconductor device and a manufacturing method thereof are disclosed. The electrostatic discharge semiconductor device includes: a substrate, an epitaxial layer and a first well region; a second well region and a third well region located on sides of the first well region respectively; a fourth well region extending in the first well region; fifth and sixth well regions on sides of the fourth well region; a first injection region and a second injection region. The second injection region in the second well region and third well region, and the first injection region in the fifth well region and sixth well region are connected to a cathode, and all injection regions in the fourth well region are connected to an anode, to form a lateral triode current discharge path, which increases the holding voltage and adjusts the avalanche breakdown voltage and trigger voltage, and enhances electrostatic protection capability.

### CROSS-REFERENCE TO RELATED APPLICATIONS

This present disclosure claims priority to a Chinese patent application No. 2024104616694, filed on Apr. 17, 2024, and entitled “electrostatic discharge semiconductor device and manufacturing method thereof”, the entire contents of which are incorporated herein by reference, including the specification, claims, drawings and abstract.

### FIELD

The present invention relates to the field of semiconductor technology, more particularly, to an electrostatic discharge semiconductor device and a manufacturing method thereof.

### BACKGROUND

ESD (Electro-Static Discharge) is an objective natural phenomenon that accompanies the entire product cycle. ESD is not easily perceived by human bodies, but it poses a serious threat to integrated circuit products. During the manufacturing, packaging, testing, and application stages of chips, the external environment and internal structures accumulate a certain amount of charge, and they can be threatened by static electricity at any time. Therefore, ESD protection devices need to be placed at each pin during chip design. LDMOS (laterally diffused metal oxide semiconductor) or SCR (Silicon Controlled Rectifier) structures are often used as ESD protection devices.

FIG. 1 shows a cross-sectional schematic diagram of a prior art silicon controlled rectifier electrostatic protection semiconductor device, and FIG. 2 shows a schematic diagram of the circuit structure corresponding to the SCR structure of FIG. 1. As shown in FIGS. 1 and 2, the electrostatic protection device of the SCR structure comprises a P-type substrate 10, an N-type well region 30 and a P-type well region 20 located on the upper part of the substrate 10. A P+ injection region 14 and an N+ injection region 13 are formed in the N-type well region 30, and a P+ injection region 12 and an N+ injection region 11 are formed in the P-type well region 20. The cathode is connected from P+ injection region 12 and N+ injection region 11, and the anode is connected from P+ injection region 14 and N+ injection region 13. The SCR path of traditional unidirectional SCR devices consists of P+ injection region 14, N-type well region 30, P-type well region 20, and N+ injection region 11. When an ESD pulse arrives, a forward pulse appears at the anode terminal. The reverse biased PN junction composed of N-type well region 30 and P-type well region 20 will undergo avalanche breakdown, thus generating a large number of carriers that continuously flow through the parasitic well resistance Rp on P-type well region 20, increasing the voltage drop Vbe between the base and emitter of the lateral parasitic NPN triode. The lateral parasitic NPN triode is triggered and operates in the amplification region when Vbe exceeds 0.7V. The amplified collector current will flow into the base of the parasitic PNP transistor, and finally the parasitic PNP triode will turn on. At this point, the parasitic NPN triode and parasitic PNP triode form effective positive feedback, and finally a low resistance lateral SCR discharge path is formed, with a high trigger voltage, low holding voltage, and easy occurrence of latch up effect. Therefore, the current electrostatic protection devices with SCR structures have poor electrostatic protection capabilities.

### SUMMARY

In view of the above issues, the purpose of the present disclosure is to provide an electrostatic discharge semiconductor device and a manufacturing method thereof to solve the problems in the prior art.

According to an aspect of the present disclosure, an electrostatic discharge semiconductor device is provided and comprises: a substrate of a first doping type; an epitaxial layer, located above the substrate; a first well region of a first doping type, extending from a surface of the epitaxial layer to a surface of the substrate; a second well region and a third well region of a second doping type, extending from the surface of the epitaxial layer to the surface of the substrate, and located on both sides of the first well region respectively and separated from the first well region; a fourth well region of the second doping type, extending from a surface of the first well region to the internal and separated from the substrate; a fifth well region and a sixth well region of the first doping type, extending from the surface of the first well region to the internal and separated from the substrate; the fifth well region and the sixth well region being symmetrically distributed on both sides of the fourth well region and separated from the fourth well region; a first injection region of the first doping type, located above the fourth well region, the fifth well region, and the sixth well region; and a second injection region of the second doping type, located above the second well region, the third well region, and the fourth well region; wherein the second injection region in the second well rejoin, the second injection region in the third well rejoin, the first injection region in the fifth well region, and the first injection region in the sixth well region are connected to a cathode, and the first injection region in the fourth well region and the second injection region in the fourth well region are connected to an anode.

Optionally, the electrostatic discharge semiconductor device further comprises: a first drift region of the first doping type, located within the first well region, surrounding the fifth well region and separated from the fourth well region; and a second drift region of the first doping type, located within the first well region, surrounding the sixth well region and separated from the fourth well region.

Optionally, the avalanche breakdown voltage between the first drift region and the fourth well region decreases as the distance between the first drift region and the fourth well region decreases; the avalanche breakdown voltage between the second drift region and the fourth well region decreases as the distance between the second drift region and the fourth well region decreases; the trigger voltage of the electrostatic discharge semiconductor device decreases as the distance between the first drift region and the fourth well region decreases; the trigger voltage of the electrostatic discharge semiconductor device decreases as the distance between the second drift region and the fourth well region decreases.

Optionally, during operation of the semiconductor device, a triode structure comprising the first injection region in the fourth well region, the fourth well region, the first well region, the fifth well region, the sixth well region, the first injection region in the fifth well region and the first injection region in the sixth well region turns on to form a first current discharge path from the anode to the cathode.

Optionally, during operation of the electrostatic discharge semiconductor device, the silicon controlled rectifier structure comprising the first injection region in the fourth well region, the fourth well region, the first well region, the second well region, the third well region, the second injection region in the second well region and the second injection region in the third well region turns on to form a second current discharge path from the anode to the cathode.

Optionally, the electrostatic discharge semiconductor device further comprises: a buried layer of the second doping type, located in the upper part of the substrate and in contact with the first region to third well region; the first injection region being the one with the highest doping concentration among all regions of the first doping type, while the second injection region being the one with the highest doping concentration among all regions of the second doping type; the doping concentration of the buried layer being second only to the higher doping concentration of the first injection region and second injection region.

Optionally, during operation of the electrostatic discharge semiconductor device, the silicon controlled rectifier structure comprising the first injection region in the fourth well region, the fourth well region, the first well region, the buried layer, the second well region, the third well region, and the second injection region in the second well region and the third well region turns on to form a third current discharge path from the anode to the cathode.

Optionally, when the electrostatic discharge semiconductor device receives an electrostatic pulse, the first current discharge path turns on before the second current discharge path and the third current discharge path, and the second current discharge path turns on before the third current discharge path; the current on the first current discharge path is less than the current on the second current discharge path, and the current on the second current discharge path is less than the current on the third current discharge path.

Optionally, the doping concentration of the first injection region in the fifth well region and the sixth well region is greater than the doping concentration of the fifth well region and the sixth well region, and the doping concentration of the fifth well region and the sixth well region is greater than the doping concentration of the first drift region and the second drift region, and the doping concentration of the first drift region and the second drift region is greater than that of the first well region.

Optionally, the electrostatic discharge semiconductor device further comprises: a field oxide layer disposed between two spaced apart injection regions, the injection regions comprising said first injection region and said second injection region; a gate oxide layer located above the fourth well region, and the field oxide layer between the fifth well region and the fourth well region is in contact with the gate oxide layer, and the field oxide layer between the sixth well region and the fourth well region is in contact with the gate oxide layer; and a field plate layer, covering a surface of the gate oxide layer and part of a surface of the field oxide layer in contact with the gate oxide layer, wherein the field plate layer is connected to the cathode.

Optionally, the electrostatic discharge semiconductor device is of a dual interdigital structure.

Optionally, the first doping type is P-type doping, while the second doping type is N-type doping.

According to another aspect of the present disclosure, a method for manufacturing an electrostatic discharge semiconductor device is provided and comprises: forming a substrate of a first doping type and a buried layer of a second doping type located in an upper part within the substrate; forming an epitaxial layer located above the substrate, the epitaxial layer covering the buried layer; forming a first well region of a first doping type extending inward from a surface of the epitaxial layer and extending to a surface of the buried layer; forming a second well region and a third well region of a second doping type extending from the surface of the epitaxial layer to the interior and extending to the surface of the buried layer, the second well region and the third well region being located on both sides of the first well region and separated from the first well region, respectively; forming a fourth well region of a second doping type extending inward from a surface of the first well region and separated from the buried layer; forming a first drift region and a second drift region of a first doping type extending from the surface of the first well region to the interior and separated from the buried layer, the first drift region and the second drift region being symmetrically distributed on both sides of the fourth well region and separated from the fourth well region; forming a fifth well region of a first doping type in the first drift region and the second drift region, and forming a sixth well region of a first doping type in the second drift region; forming a plurality of spaced field oxide layers located above and outside the epitaxial layer; and forming a plurality of spaced injection regions with the field oxide layer as an interval, injection region located within well region and comprising first injection region and second injection region, the first injection region being of the first doping type, and the second injection region being of the second doping type, respectively, wherein, the second injection region in the second well region, the second injection region in the third well region, and the first injection region in the fifth well region, and the first injection region in the sixth well region are connected to the cathode, and the first injection region in the fourth well region and the second injection region in the fourth well region are connected to the anode.

According to another aspect of the present disclosure, there is provided an integrated circuit comprising the above electrostatic discharge semiconductor device.

In the electrostatic discharge semiconductor device and the manufacturing method thereof provided by the present disclosure, only a second injection region is set in the second well region and the third well region, and no first injection region is set, thereby saving a resistor structure in the SCR structure. Moreover, by setting up the fifth well region and the P+ injection region in the fifth well region, the sixth well region and the P+ injection region in the sixth well region, an independent triode current discharge path is formed (the first current discharge path). The first current discharge path is very easy to turn on, and the trigger voltage of the device is low which can well protect the device. The device itself also has a lateral SCR discharge path (the second current discharge path), which enhances the holding voltage of the device through the cooperation of the two current discharge paths. Moreover, the avalanche breakdown voltage between the well regions can be adjusted by adjusting the distance between the fifth well region and the fourth well region (the distance between the sixth well region and the fourth well region) to regulate the triggering voltage of the device, thus enhancing the electrostatic protection capability of electrostatic discharge semiconductor devices, reducing device size, and simplifying manufacturing processes. Furthermore, the shorter the distance between the fifth and the fourth well region (the distance between the sixth well region and the fourth well region), the lower the avalanche breakdown voltage and the triggering voltage of the electrostatic discharge semiconductor device, and the better the device protection performance, and it is suitable for electrostatic protection in low voltage range (5V-50V).

Furthermore, the electrostatic discharge semiconductor device of this embodiment adds a first drift region and a second drift region, which further adjusts the ion doping concentration between the fifth well region and the fourth well region and he ion doping concentration between the sixth well region and the fourth well region, reduces the carrier migration efficiency on the device surface, further reduces the current amplification factor, and increases the holding voltage. The distance between the fifth well region and fourth well region (the distance between the sixth well region and the fourth well region) also has a wider adjustment range, and thus the adjustment range of avalanche breakdown voltage and trigger voltage of electrostatic discharge semiconductor devices is wider, which can be applied to electrostatic protection at higher voltages (0V-100V).

Further, a heavily doped buried layer is formed on the upper part of the substrate of the electrostatic discharge semiconductor device, so that a longitudinal SCR discharge path (the third current discharge path) can be formed on the basis of the lateral SCR discharge path (the second current discharge path) and the triode current discharge path (the first current discharge path), and the longitudinal SCR discharge path can improve the holding voltage of SCR. Due to the heavy doping of the buried layer, the longitudinal third current discharge path gradually becomes the dominant current discharge path, achieving current discharge inside the device and avoiding the accumulation of discharge heat on the device surface. Moreover, the buried layer and substrate, as well as the second and third well regions and the epitaxial layer, provide good internal and external isolation for the device to prevent leakage.

Furthermore, the first current discharge path turns on before the second current discharge path and the third current discharge path, and the path is shorter and has a lower trigger voltage for the device. This allows for faster current discharge when electrostatic pulses occur, protecting the device. Moreover, using the third current discharge path as the main discharge path can also extend the current discharge path and improve the holding voltage of the device.

Further, a field plate layer connected to the cathode is set up to improve the electric field distribution in the fourth well region, resulting in a smoother peak electric field variation below the field plate layer and enhancing the reliability and forward voltage resistance of the device.

Further, the electrostatic discharge semiconductor devices use a dual interdigital structure to achieve layout symmetry, which improves the device's failure current and enhances its electrostatic protection performance.

### BRIEF DESCRIPTION OF THE DRAWINGS

The above and other objectives, features, and advantages of the present disclosure will become clearer through the following description of embodiments of the present disclosure with reference to the accompanying drawings.

FIG. 1 shows a cross-sectional schematic diagram of a prior art silicon controlled rectifier electrostatic protection semiconductor device;

FIG. 2 shows a schematic diagram of the circuit structure corresponding to the SCR structure in FIG. 1;

FIG. 3 shows a schematic cross-sectional view of an electrostatic discharge semiconductor device according to an embodiment of the present disclosure;

FIG. 4 shows a schematic diagram of the circuit structure corresponding to the SCR structure in FIG. 3;

FIGS. 5A-5D show cross-sectional schematic diagrams of various stages of the manufacturing method of the electrostatic discharge semiconductor device according to an embodiment of the present disclosure.

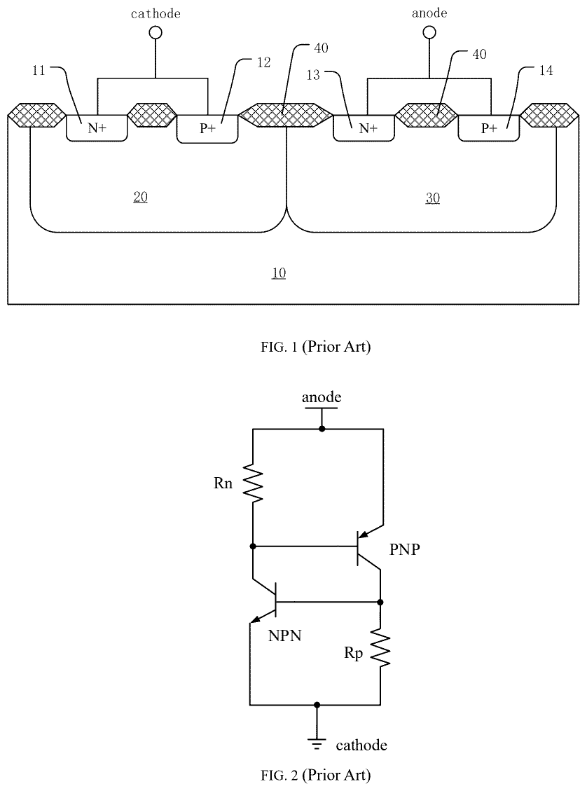

### DETAILED DESCRIPTION

Various embodiments of the present disclosure will be described in more details below with reference to the accompanying drawings. In each accompanying drawing, the same elements are denoted by the same or similar reference numerals. For clarity, the various parts in the accompanying drawings are not drawn to scale. In addition, some well-known parts may not be shown. For simplicity, the semiconductor structure obtained after several steps can be described in one drawing.

When describing the structure of a device, for a layer or region as being located “above” or “up” another layer or region, it can refer to being directly located above another layer or region, or containing other layers or regions between the layer and another layer or region. Moreover, if the device is flipped, that layer or region will be located “below” or “under” another layer or region. In this application, the term “semiconductor structure” refers to the collective term for the entire semiconductor structure formed in various steps of manufacturing semiconductor devices, including all layers or regions that have already been formed.

Unless otherwise specified in the following text, each layer or region of a semiconductor device may be composed of materials known to those skilled in the art. Semiconductor materials include, e.g., groups III-V semiconductors such as GaAs, InP, GaN, SiC, and group IV semiconductors, e.g., Si and Ge. Gate conductors and electrode layers can be formed of various conductive materials, such as metal layers, doped polycrystalline silicon layers, or stacked gate conductors including metal layers and doped polycrystalline silicon layers, or other conductive materials, such as TaC, TiN, TaSiN, HfSiN, TiSiN, TiCN, TaAlC, TiAlN, TaN, PtSix, Ni3Si, Pt, Ru, W, and combination with various conductive materials mentioned above.

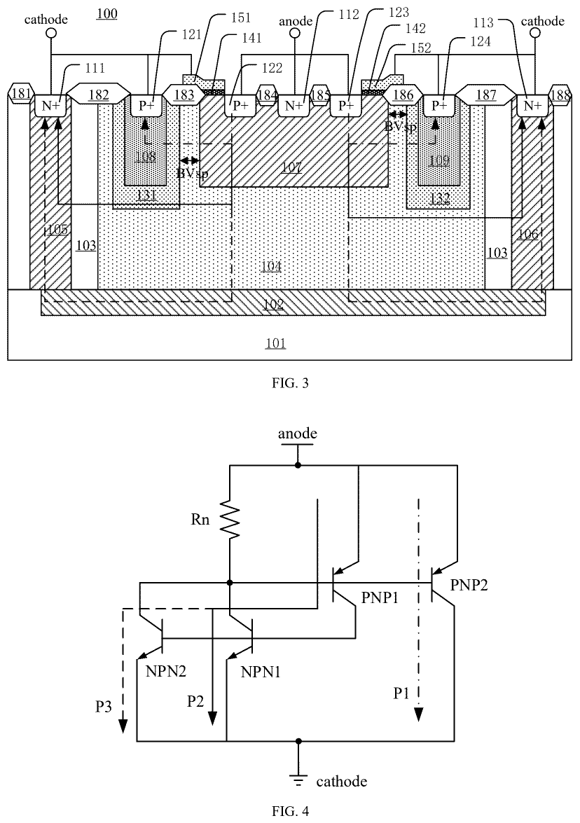

FIG. 3 shows a schematic cross-sectional view of an electrostatic discharge semiconductor device according to an embodiment of the present disclosure, and FIG. 4 shows a schematic circuit structure corresponding to the SCR structure of FIG. 3.

As shown in FIG. 3, the electrostatic discharge semiconductor device 100 of this embodiment comprises a substrate 101, a buried layer 102 located in the upper part of the substrate 101, and an epitaxial layer 103 located above the substrate 101. The substrate 101 has a first doping type, and the buried layer 102 has a second doping type. The buried layer 102 is located inside the substrate 101 and at the top of the substrate 101. The upper surface of the buried layer 102 is flush with the upper surface of the substrate 101. In this embodiment, the first doping type may be P-type doping, and the second doping type may be N-type doping. Of course, in other embodiments, the first doping type can also be N-type doping, and the second doping type can also be P-type doping. The epitaxial layer 103 covers the buried layer 102, and the epitaxial layer 103 can be P-type doped or N-type doped. In this embodiment, the epitaxial layer 103 is, for example, P-type doping.

Furthermore, the epitaxial layer 103 is distributed with a first well region 104, a second well region 105, and a third well region 106. The first well region 104, the second well region 105, and the third well region 106 all extend inward from the upper surface of the epitaxial layer 103, and the bottom is in contact with the buried layer 102, that is, the injection depth of the first well region 104, the second well region 105, and the third well region 106 is the same as the thickness of the epitaxial layer 103. The first well region 104 has a first doping type, such as P-type doping, while the second well region 105 and the third well region 106 have a second doping type, such as N-type doping. That is, the first well region 104 is a P-type well region, and the second well region 105 and the third well region 106 are N-type well regions. Moreover, in the lateral direction, the first well region 104 is distributed in the middle position of the epitaxial layer 103, while the second well region 105 and the third well region 106 are distributed on both sides of the first well region 104 and separated from the region by a certain distance. The second well region 105 and the third well region 106 are, e.g., symmetrically distributed on the two sides of the first well region 104.

Furthermore, the first well region 104 is also distributed with the fourth well regions 107, the fifth well regions 108, and the sixth well regions 109. The fourth well region 107, the fifth well region 108, and the sixth well region 109 all extend inward from the upper surface of the first well region 104, and are separated from the buried layer 102 at the bottom, that is, the injection depth of the fourth well region 107, the fifth well region 108, and the sixth well region 109 is smaller than that of the first well region 104. Moreover, the injection depths of the fourth well region 107, the fifth well region 108, and the sixth well region 109 can be the same. In this embodiment, the fourth well region 107 has a second doping type, such as N-type doping, while the fifth well region 108 and the sixth well region 109 have a first doping type, such as P-type doping. That is, the fifth well region 108 and the sixth well region 109 are P-type well regions, and the fourth well region 107 is an N-type well region. Moreover, in the lateral direction, the fourth well region 107 is distributed in the middle of the first well region 104, while the fifth well region 108 and the sixth well region 109 are distributed on both sides of the fourth well region 107 and separated from it by a certain distance. The fifth well region 108 and the sixth well region 109 are, e.g., symmetrically distributed on the two sides of the fourth well region 107.

The fourth well region 107 is distributed with a first injection region and a second injection region. The first injection region and the second injection region have a first doping type and a second doping type, respectively. That is, the first injection region can be a P+ injection region, and the second injection region can be an N+ injection region. Within the fourth well region 107, there are spaced P+ injection regions 122, N+ injection regions 112, and P+ injection regions 123. There are N+ injection region 111 distributed in the second well region 105, and N+ injection region 113 distributed in the third well region 106. The fifth well region 108 is distributed with a P+ injection region 121, and the sixth well region 109 is distributed with a P+ injection region 124. The injection regions are formed at the upper part of each well region and can be formed by injecting from the surface of the well region to the inside. There are also a plurality of field oxide layers distributed among the gaps in each well region and injection region, e.g., field oxide layer 181, field oxide layer 182, field oxide layer 183, field oxide layer 184, field oxide layer 185, field oxide layer 186, field oxide layer 187, and field oxide layer 188, and the plural filed oxide layers sequentially separate the plural injection regions. In addition, the N+ injection region 111 in the second well region 105, the N+ injection region 113 in the third well region 106, the P+ injection region 121 in the fifth well region 108, and the P+ injection region 124 in the sixth well region 109 are all connected to the cathode, while the P+ injection regions 122, the N+ injection region 112, and the P+ injection region 123 in the fourth well region 107 are all connected to the anode.

The presence of the fifth well region 108 and the sixth well region 109 can increase the ion doping concentration in the first well region 104 outside the fourth well region 107, reduce the carrier migration efficiency on the device surface, decrease the current amplification factor, and increase the holding voltage. By adjusting the distance between the fifth well region 108 and the fourth well region 107 (the distance between the sixth well region 109 and the fourth well region 107), the avalanche breakdown voltage between the well regions and the trigger voltage when the SCR turns on can also be adjusted. Specifically, the avalanche breakdown voltage between the fifth well region 108 and the fourth well region 107 (the avalanche breakdown voltage between the sixth well region 109 and the fourth well region 107), and the trigger voltage of the device, decrease as the distance between them decreases. That is, the larger the distance between the fifth well region 108 and the fourth well region 107 (the distance between the sixth well region 109 and the fourth well region 107), the higher the avalanche breakdown voltage and the device trigger voltage. On the contrary, the smaller the distance between the fifth well region 108 and the fourth well region 107 (the distance between the sixth well region 109 and the fourth well region 107), the lower the avalanche breakdown voltage and the device trigger voltage. Thus, the electrostatic discharge semiconductor device can be applied to different voltage ports, e.g., it is suitable for low voltage protection environments of 5V-50V.

Furthermore, in order to expand the voltage protection range of the device, the electrostatic discharge semiconductor device 100 of this embodiment further comprises a first drift region 131 and a second drift region 132. The first drift region 131 has a first doping type and is located within the first well region 104, surrounding the fifth well region 108 and separated from the fourth well region 107 by a certain distance. The second drift region 132 has the first doping type and is located within the first well region 104, surrounding the sixth well region 109 and separated from the fourth well region 107 by a certain distance. In this embodiment, the doping concentration of all first injection regions may be the same, and the doping concentration of all second injection regions may be the same. Moreover, among all regions with the first doping type (including well region, injection region, drift region, and substrate), the doping concentration of the first injection region is the highest, and among all regions with the second doping type (including the well region, the injection region, the buried layer, and the epitaxial layer), the doping concentration of the second injection region is also the highest. Specifically, for example, the doping concentration of the P+ injection region 121 in the fifth well region 108 and the P+ injection region 124 in the sixth well region 109 is greater than that of the fifth well region 108 and the sixth well region 109, the doping concentration of the fifth well region 108 and the sixth well region 109 is greater than that of the first drift region 131 and the second drift region 132, and the doping concentration of the first drift region 131 and the second drift region 132 is greater than that of the first well region 104. Furthermore, the doping concentration of the buried layer 102 located in the substrate 101 is second only to the higher doping concentration of the first injection region and the second injection region. That is, the doping concentration of the buried layer 102 is second only to the injection region with the highest doping concentration.

The distance between the first drift region 131 and the fourth well region 107 (the distance between the second drift region 132 and the fourth well region 107) is BVsp. The avalanche breakdown voltage between the first drift region 131 and the fourth well region 107, and the triggering voltage of the electrostatic discharge semiconductor device 100, decreases with the shortening of the distance BVsp between the first drift region 131 and the fourth well region 107. The avalanche breakdown voltage between the second drift region 132 and the fourth well region 107, and the triggering voltage of the electrostatic discharge semiconductor device 100, decreases with the shortening of the distance BVsp between the second drift region 132 and the fourth well region 107. At this time, the upper limit of the triggering voltage is further increased. In addition, the setting of the first drift region 131 and the second drift region 132 can further increase the ion doping concentration in the first well region 104 outside the fourth well region 107, reduce the carrier migration efficiency on the device surface, further reduce the current amplification factor and increase the holding voltage. The doping types of the first drift region 131 and the second drift region 132 are the same as those of the fifth well region 108 and the sixth well region 109, all of which are P-type doping. The presence of the first drift region 131 allows for a larger adjustable range of the distances between the fifth well region 108 and the fourth well region 107, resulting in higher ion concentrations within the range. The presence of the second drift region 132 allows for a larger adjustable range of the distances between the sixth well region 109 and the fourth well region 107, resulting in higher ion concentrations within the range. This makes it suitable for use in higher voltage ranges, such as ports with voltage ranges of 0V-100V.

Furthermore, the electrostatic discharge semiconductor device 100 of this embodiment further comprises a gate oxide layer 141, a gate oxide layer 142, a field plate layer 151, and a field plate layer 152. The gate oxide layers 141 and 142 are both located above the fourth well region 107. The field oxide layer 183 between the fifth well region 108 and the fourth well region 107 is in contact with the gate oxide layer 141, and the field oxide layer 186 between the sixth well region 109 and the fourth well region 107 is in contact with the gate oxide layer 142. Field plate layer 151 covers the surface of gate oxide layer 141 and part of the surface of field oxide layer 183 in contact with gate oxide layer 141. Field plate layer 152 covers the surface of gate oxide layer 142 and part of the surface of field oxide layer 186 in contact with gate oxide layer 142. Both field plate layers 151 and 152 can be polycrystalline silicon layers, and they are also connected to the cathode. Connecting the field plate layer to the cathode can change the electric field in the fourth well region 107, making the peak electric field beneath the field plate layer change more smoothly, thereby improving the reliability of the device.

In this embodiment, the electrostatic discharge semiconductor device 100, for example, uses a dual interdigital structure to achieve layout symmetry and enhance failure current. So, the electrostatic discharge semiconductor device 100 of this embodiment can be symmetrically distributed with the fourth well region 107 as the center or with the N+ injection region 112 as the symmetrical center.

FIG. 4 shows the SCR circuit structure corresponding to FIG. 3. As it is a dual interdigital structure, this embodiment will first explain from the right side. As shown in FIG. 4, when a forward pulse arrives, a positive voltage is generated on the anode, and the electrostatic discharge semiconductor device 100 forms a PNP parasitic triode PNP1 by the P+ injection region 123 in the fourth well region 107, the fourth well region 107, and the first well region 104 (the second drift region 132). The PNP parasitic triode PNP2 is formed by the P+ injection region 123 in the fourth well region 107, the fourth well region 107, the first well region 104, the second drift region 132, the sixth well region 109, and the P+ injection region 124 in the sixth well region 109. The NPN parasitic triode NPN1 is formed by the fourth well region 107, the first well region 104, the epitaxial layer 103, the third well region 106, and the N+ injection region 113 within the third well region 106. Or the NPN parasitic triode NPN1 is formed by the fourth well region 107, the first well region 104, the sixth well region 109, the epitaxial layer 103, the third well region 106, and the N+ injection region 113 within the third well region 106. Parasitic well resistance Rn is generated in the fourth well region 107. The forward voltage on the anode raises the voltage across resistor Rn, causing PNP2 and PNP1 to turn on, which in turn raises the base current of NPN1 and turns it on.

That is, when the semiconductor device is in operation, the triode structure PNP2 composed of the P+ injection region 123 in the fourth well region 107, the fourth well region 107, the first well region 104, the second drift region 132, the sixth well region 109, and the P+ injection region 124 in the sixth well region 109 turns on to form a first current discharge path P1 from the anode to the cathode. Then, the silicon controlled rectifier structure composed of the P+ injection region 123 in the fourth well region 107, the fourth well region 107, the first well region 104, the (second drift region 132) epitaxial layer 103, the third well region 106, and the N+ injection region 113 in the third well region 106 turns on to form a P-N-P-N SCR discharge path from the anode to the cathode. That is, the solid arrow in FIG. 4 shows second current discharge path P2 from the anode to the cathode. When there is electrostatic pulse on the cathode, a diode path can be formed from the P+ injection region 124, the sixth well region 109, the second drift region 132, the first well region 104, the fourth well region 107, and the N+ injection region 112 between the cathode and the anode to achieve reverse voltage resistance without setting additional diodes. In this embodiment, since the third well region 106 only has an N+ injection region and no P+ injection region, compared with the SCR structure shown in FIG. 2, a well resistor Rp can be omitted, thereby reducing the device size and manufacturing cost.

Due to the presence of the fifth well region 108, the sixth well region 109, the P+ injection region 121, and the P+ injection region 124, the parasitic triode PNP2 becomes an independent first current discharge path P1, and this first current discharge path P1 is extremely easy to turn on, resulting in a low triggering voltage of the device and a good protective effect on the device.

Furthermore, due to the presence of a buried layer 102 in the substrate 101, the buried layer 102 provides the basis for a longitudinal current discharge path. The NPN parasitic triode NPN2 is formed by the fourth well region 107, the first well region 104, the buried layer 102, the third well region 106, and the N+ injection region 113 within the third well region 106. When there is electrostatic pulse at the anode, the silicon controlled rectifier structure composed of the P+ injection region 123 in the fourth well region 107, the fourth well region 107, the first well region 104, the buried layer 102, the third well region 106, and the N+ injection region 113 in the third well region 106 also turns on to form a third current discharge path P3 from the anode to the cathode, as shown by the dashed arrow in FIG. 3. Since the doping concentration of the buried layer 102 is second only to the first injection region or second injection region with the highest doping concentration, the third current discharge path P3 can be referred to as the dominant discharge path. In this embodiment, the first current discharge path P1 and the second current discharge path P2 are both horizontal paths, while the third current discharge path P3 is a longitudinal path. The horizontal path provides base current for the longitudinal path, and when PNP2 turns on, it causes the base current of NPN1 and NPN2 to rise. The current amplification factor of NPN2 is smaller than that of NPN1, making the longitudinal path the last one to turn on and the dominant path. Due to the addition of a vertical dominant discharge path, current discharge is achieved inside the device to avoid the accumulation of discharge heat on the surface of the device.

That is, when the electrostatic discharge semiconductor device 100 receives an electrostatic pulse, the first current discharge path P1 turns on before the second current discharge path P2, and the second current discharge path P2 turns on before the third current discharge path P3. After turning on, the amplification factor of the base current of parasitic triode NPN1 is greater than that of parasitic triode NPN2, so the current on the second current discharge path P2 is smaller than that on the third current discharge path P3. Therefore, the third current discharge path P3 becomes the dominant current discharge path, and the current path is extended, resulting in a higher holding voltage of the device.

The above takes the right side structure of the semiconductor device as an example. Due to the symmetrical structure of the electrostatic discharge semiconductor device 100, the left side actually forms the same circuit structure as that in FIG. 4. A corresponding current discharge path is shown in FIG. 3, and it will not be described again here.

Furthermore, the buried layer 102 and substrate 101, the second well region 105 and the external epitaxial layer 103, the third well region 106 and the external epitaxial layer 103 provide internal and external isolation of the device, enabling it to have good electrostatic protection and prevent leakage.

In summary, the electrostatic discharge semiconductor device of this embodiment forms a first current discharge path by the fifth well region and the P+ injection region in the fifth well region, and the sixth well region and the P+ injection region in the sixth well region connected to the cathode, and the first current discharge path is easy to turn on, and the triggering voltage of the device is low, which provides good protection for the device. Moreover, by adjusting the distance between the first drift region and the fourth well region (the distance between the second drift region and the fourth well region), the avalanche breakdown voltage between the well regions and the holding voltage of the device can also be adjusted, making the device applicable to ports in different voltage ranges. This can effectively avoid the risks of high trigger voltage causing premature circuit breakdown and low holding voltage causing the device to enter latch up. Meanwhile, due to the presence of heavily doped buried layers, a longitudinal third current discharge path can also be formed, which is the internal current path and the dominant path, thus avoiding the concentration of discharge heat on the device surface and increasing the failure current of the device. The field plate layer connected to the cathode can also improve the electric field distribution in the fourth well region, thereby enhancing the forward withstand voltage and reliability of the device.

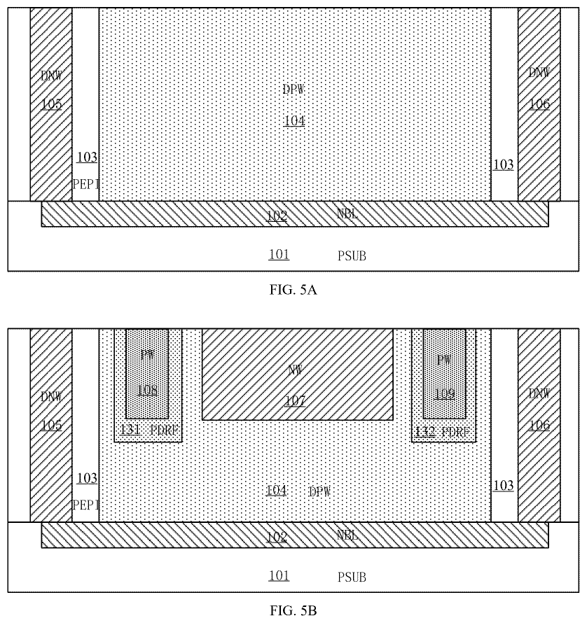

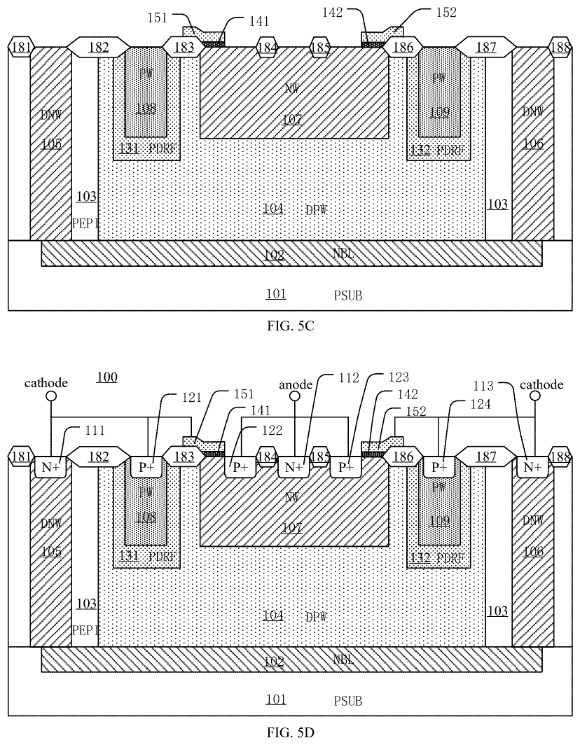

FIGS. 5A-5D show cross-sectional schematic diagrams of various stages of the manufacturing method of the electrostatic discharge semiconductor device according to an embodiment of the present disclosure. The semiconductor device shown in FIG. 3 is fabricated by the process steps of FIGS. 5A-5D to further enhance the electrostatic protection capability of the semiconductor device. The manufacturing method of the electrostatic discharge semiconductor device in the embodiment of the present application will be introduced in conjunction with FIGS. 5A-5D.

As shown in FIG. 5A, first, a substrate 101 with a first doping type and a buried layer 102 with a second doping type located in the upper part of the substrate 101 are formed. Specifically, substrate 101 is a P-type doped silicon substrate P-SUB. The buried layer 102 is formed inside the substrate 101, which is an N-type doped layer structure NBL located at the upper part of the substrate 101. The upper surface of the buried layer 102 is, for example, flush with the upper surface of the substrate 101. Next, an epitaxial layer 103 is formed above the substrate 101, and the epitaxial layer 103 covers the buried layer 102. The epitaxial layer 103 can be either N-type doped or P-type doped. Here, the P-type doped epitaxial layer 103 (PEPI) is taken as an example for illustration. Then, a well region injection is performed along the surface of the epitaxial layer 101, forming a first well region 104 (DPW) with the first doping type and extending inward from the surface of the epitaxial layer 103 and extending to the surface of the buried layer 102, and a second well region 105 (DNW) and a third well region 106 (DNW) with a second doping type are formed, which extend from the surface of the epitaxial layer 103 to the interior and extending to the surface of the buried layer 102. That is, the depths of the first well region 104, the second well region 105, and the third well region 106 can be consistent and the same as the thickness of the epitaxial layer 103. The first well region 104 is distributed in the middle position, and the second well region 105 and the third well region 106 are located on both sides of the first well region 104 and spaced from it by a certain distance. The electrostatic discharge semiconductor structure of this embodiment is a dual interdigital structure, and here the second well region 105 and the third well region 106 are symmetrically distributed on both sides of the first well region 104, and the lateral width of the second well region 105 and the third well region 106 is smaller than that of the first well region 104.

Furthermore, as shown in FIG. 5B, well injection is performed from the surface of the first well region 104, and a fourth well region 107 (NW) with a second doping type and extending inward from the surface of the first well region 104 and separated from the buried layer 102 is formed in the first well region 104. A first drift region 131 (PDRF) and a second drift region 132 (PDRF) with a first doping type are also formed, extending inward from the surface of the first well region 104 and separated from the buried layer 102. The first drift region 131 and the second drift region 132 are symmetrically distributed on the two sides of the fourth well region 107 and separated from the region. The injection depth of the first drift region 131 and the second drift region 132 is greater than the injection depth of the fourth well region 107. Next, a fifth well region 108 (PW) with the first doping type is formed in the first drift region 131 and a sixth well region 109 (PW) with the first doping type is formed in the second drift region 132. The injection depth of the fifth well region 108 is smaller than that of the first drift region 131, and the injection depth of the sixth well region 109 is smaller than that of the second drift region 132. The fourth well region 107 to the sixth well region 109 are all distributed within the first well region 104, and the bottoms of the three well regions are separated from the buried layer 102 by a certain distance, that is, the injection depth of the fourth well region 107 to the sixth well region 109 is smaller than that of the first well region 104. The fourth well region 107 is distributed in the middle position, and the fifth well region 108 and the sixth well region 109 are symmetrically distributed on both sides of the fourth well region 107 and separated from the fourth well region 107 by a certain distance.

Next, as shown in FIG. 5C, a plurality of spaced field oxide layers are formed above and outside the epitaxial layer 103. Specifically, field oxygen isolation is performed on the surface of epitaxial layer 103, i.e., forming a plurality of mutually isolated field oxide layers, such as field oxide layer 181, field oxide layer 182, field oxide layer 183, field oxide layer 184, field oxide layer 185, field oxide layer 186, field oxide layer 187, and field oxide layer 188. The formation of the field oxide layers uses conventional processes, such as depositing an oxide layer on the surface of the epitaxial layer 103, then depositing a hard mask, etching using the mask, and finally growing field oxygen at high temperature, and removing the hard mask. The specific processes are not described in detail. Next, a gate oxide layer 141 and a gate oxide layer 142 are formed on the surface of the fourth well region 107. The gate oxide layer 141 is adjacent to the field oxide layer located between the fourth well region 107 and the fifth well region 108, and the gate oxide layer 142 is adjacent to the field oxide layer located between the fourth well region 107 and the sixth well region 109. That is, the gate oxide layer 141 is adjacent to the field oxide layer 183, and the gate oxide layer 142 is adjacent to the field oxide layer 186. Field plate layer 151 is formed on the surfaces of gate oxide layer 141 and field plate layer 152 is formed on the surfaces of gate oxide layer 142. Field plate layer 151 and field plate layer 152 are both, e.g., polycrystalline silicon layers. Field plate layer 151 covers gate oxide layer 141 and part of field oxide layer 183, while field plate layer 152 covers gate oxide layer 142 and part of field oxide layer 186. The formation process of gate oxide layer and polycrystalline silicon layer is a conventional process, and the polycrystalline silicon layer is formed by, e.g., chemical vapor deposition, which is not limited in detail here.

Next, as shown in FIG. 5D, plural spaced injection regions are formed with the above a plurality of field oxide layers as intervals, comprising a first injection region and a second injection region. The first injection region (P+ injection region) and the second injection region (N+ injection region) have the first doping type and the second doping type, respectively. Specifically, P+ or N+ injection is performed in well region between two adjacent field oxide layers to form a plurality of P+ or N+ injection regions. For example, N+ injection region 111 is formed in the second well region 105 (DNW), P+ injection region 121 is formed in the fifth well region 108 (PW), P+ injection region 122, N+ injection region 112, and P+ injection region 123 are formed in the fourth well region 107 (NW), P+ injection region 124 is formed in the sixth well region 109 (PW), and N+ injection region 113 is formed in the third well region 106 (DNW).

In this embodiment, the doping concentration of all P+ injection regions may be the same, and the doping concentration of all N+ injection regions may be the same. Moreover, among all regions with the first doping type (including the well regions, the injection regions, the drift regions, and the substrate), the doping concentration of the P+ injection region is the highest. Among all regions with the second doping type (including the well regions, the injection regions, the buried layer, and the epitaxial layer), the doping concentration of the N+ injection region is also the highest. The doping concentration of the buried layer 102 located in the substrate 101 is second only to the higher doping concentration of the P+ injection region and the N+ injection region.

Furthermore, the anode and cathode of the semiconductor device are formed, wherein the N+ injection region 111 in the second well region 105, the N+ injection region 113 in the third well region 106, the field plate layer 151, the field plate layer 152, the P+ injection region 121 in the fifth well region 108 and the P+ injection region 124 in the sixth well region 109 are both connected to the cathode, and the P+ injection region 122, the P+ injection region 123 and the N+ injection region 112 in the fourth well region 107 are all connected to the anode. The fifth well region 108 and the sixth well region 109 are floating without circuit connection to form the structure shown in FIG. 3. Here, the manufacturing processes of the electrode layer above the various injection regions are omitted.

In addition, the present disclosure also provides an integrated circuit comprising the electrostatic discharge semiconductor device described in the above embodiments.

In summary, by using the electrostatic discharge semiconductor device, as well as the manufacturing method thereof and the integrated circuit of the embodiments of the present disclosure, only the second injection region is provided in the second well region and the third well region, without providing the first injection region, thereby saving a resistor structure in the SCR structure and reducing device size. Moreover, by setting up the fifth well region, the P+ injection region in the fifth well region, the six well region and the P+ injection region in the sixth well region which are connected to the cathode, a triode lateral current discharge path (the first current discharge path) is formed. The first current discharge path turns on before the second discharge path, and the path is shorter and has a lower triggering voltage for the device, which allows for faster current discharge when electrostatic pulses occur, protecting the device.

Furthermore, a fifth well region and a sixth well region are set up, and the avalanche breakdown voltage between the well regions is adjusted by adjusting the distance between the fifth well region and the fourth well region (the distance between the sixth well region and the fourth well region) to regulate the triggering voltage of the device and enhance the electrostatic protection capability of the electrostatic discharge semiconductor device. The shorter the distance between the fifth well region and the fourth well region (the distance between the sixth well region and the fourth well region), the lower the avalanche breakdown voltage and the triggering voltage of the electrostatic discharge semiconductor device, and the better the device protection performance. It is suitable for electrostatic protection in the low voltage range (5V-50V). Moreover, the addition of the first drift region further regulates the ion doping concentration between the fifth well region and the fourth well region, the addition of the second drift region further regulates the ion doping concentration between the sixth well region and the fourth well region, the carrier migration efficiency on the device surface is reduced, the current amplification facto is further reduced, and the holding voltage is increased. Moreover, the distance between the first drift region and the fourth well region (the distance between the second drift region and the fourth well region) has a wider adjustment range, so the adjustment range of avalanche breakdown voltage and the triggering voltage of electrostatic discharge semiconductor devices is wider, which can be applied to higher voltage (0-100V) electrostatic protection.

Furthermore, a heavily doped buried layer is formed on the upper part of the substrate of the electrostatic discharge semiconductor device, so that a longitudinal SCR discharge path (the third current discharge path) can be formed on the basis of the original SCR transverse current discharge path (the second current discharge path) and the independent triode current discharge path (the first current discharge path), and the longitudinal SCR discharge path can improve the holding voltage of SCR. Due to the heavy doping of the buried layer, the longitudinal third current discharge path gradually becomes the dominant current discharge path, achieving current discharge inside the device and avoiding the accumulation of discharge heat on the device surface.

According to the embodiments of the present disclosure described above, these embodiments do not describe all details and do not limit the disclosure to only the specific embodiments described. Obviously, based on the above description, many modifications and changes can be made. This specification selects and specifically describes these embodiments in order to better explain the principles and practical applications of the present disclosure, so that those skilled in the art can make good use of the present disclosure and make modifications based on the present disclosure. The present disclosure is limited only by the claims and their full scope and equivalents.

What is claimed is:

1. An electrostatic discharge semiconductor device, comprising:
a substrate of a first doping type;
an epitaxial layer, located above the substrate;
a first well region of a first doping type, extending from a surface of the epitaxial layer to a surface of the substrate;
a second well region and a third well region of a second doping type, extending from the surface of the epitaxial layer to the surface of the substrate, and located on both sides of the first well region respectively and separated from the first well region;
a fourth well region of the second doping type, extending from a surface of the first well region to the internal and separated from the substrate;
a fifth well region and a sixth well region of the first doping type, extending from the surface of the first well region to the internal and separated from the substrate; the fifth well region and the sixth well region being symmetrically distributed on both sides of the fourth well region and separated from the fourth well region;
a first injection region of the first doping type, located above the fourth well region, the fifth well region, and the sixth well region; and
a second injection region of the second doping type, located above the second well region, the third well region, and the fourth well region;
wherein the second injection region in the second well rejoin, the second injection region in the third well rejoin, the first injection region in the fifth well region, and the first injection region in the sixth well region are connected to a cathode, and the first injection region in the fourth well region and the second injection region in the fourth well region are connected to an anode.

2. The electrostatic discharge semiconductor device of claim 1, further comprising:
a first drift region of the first doping type, located within the first well region, surrounding the fifth well region and separated from the fourth well region; and
a second drift region of the first doping type, located within the first well region, surrounding the sixth well region and separated from the fourth well region.

3. The electrostatic discharge semiconductor device of claim 2, wherein,
the avalanche breakdown voltage between the first drift region and the fourth well region decreases as the distance between the first drift region and the fourth well region decreases;
the avalanche breakdown voltage between the second drift region and the fourth well region decreases as the distance between the second drift region and the fourth well region decreases;
the trigger voltage of the electrostatic discharge semiconductor device decreases as the distance between the first drift region and the fourth well region decreases;
the trigger voltage of the electrostatic discharge semiconductor device decreases as the distance between the second drift region and the fourth well region decreases.

4. The electrostatic discharge semiconductor device of claim 1, wherein during operation of the semiconductor device, a triode structure comprising the first injection region in the fourth well region, the fourth well region, the first well region, the fifth well region, the sixth well region, the first injection region in the fifth well region and the first injection region in the sixth well region turns on to form a first current discharge path from the anode to the cathode.

5. The electrostatic discharge semiconductor device of claim 4, wherein during operation of the electrostatic discharge semiconductor device, the silicon controlled rectifier structure comprising the first injection region in the fourth well region, the fourth well region, the first well region, the second well region, the third well region, the second injection region in the second well region and the second injection region in the third well region turns on to form a second current discharge path from the anode to the cathode.

6. The electrostatic discharge semiconductor device of claim 5, further comprising:
a buried layer of the second doping type, located in the upper part of the substrate and in contact with the first region to third well region; the first injection region being the one with the highest doping concentration among all regions of the first doping type, while the second injection region being the one with the highest doping concentration among all regions of the second doping type; the doping concentration of the buried layer being second only to the higher doping concentration of the first injection region and second injection region.

7. The electrostatic discharge semiconductor device of claim 6, wherein during operation of the electrostatic discharge semiconductor device, the silicon controlled rectifier structure comprising the first injection region in the fourth well region, the fourth well region, the first well region, the buried layer, the second well region, the third well region, and the second injection region in the second well region and the third well region turns on to form a third current discharge path from the anode to the cathode.

8. The electrostatic discharge semiconductor device of claim 7, wherein when the electrostatic discharge semiconductor device receives an electrostatic pulse, the first current discharge path turns on before the second current discharge path and the third current discharge path, and the second current discharge path turns on before the third current discharge path; the current on the first current discharge path is less than the current on the second current discharge path, and the current on the second current discharge path is less than the current on the third current discharge path.

9. The electrostatic discharge semiconductor device of claim 2, wherein the doping concentration of the first injection region in the fifth well region and the sixth well region is greater than the doping concentration of the fifth well region and the sixth well region, and the doping concentration of the fifth well region and the sixth well region is greater than the doping concentration of the first drift region and the second drift region, and the doping concentration of the first drift region and the second drift region is greater than that of the first well region.

10. The electrostatic discharge semiconductor device according to claim 1, further comprising:
a field oxide layer disposed between two spaced apart injection regions, the injection regions comprising said first injection region and said second injection region;
a gate oxide layer located above the fourth well region, and the field oxide layer between the fifth well region and the fourth well region is in contact with the gate oxide layer, and the field oxide layer between the sixth well region and the fourth well region is in contact with the gate oxide layer; and
a field plate layer, covering a surface of the gate oxide layer and part of a surface of the field oxide layer in contact with the gate oxide layer, wherein the field plate layer is connected to the cathode.

11. The electrostatic discharge semiconductor device of claim 1, wherein the electrostatic discharge semiconductor device is of a dual interdigital structure.

12. The electrostatic discharge semiconductor device of claim 1, wherein the first doping type is P-type doping, while the second doping type is N-type doping.

13. A method for manufacturing an electrostatic discharge semiconductor device, comprising:
forming a substrate of a first doping type and a buried layer of a second doping type located in an upper part within the substrate;
forming an epitaxial layer located above the substrate, the epitaxial layer covering the buried layer;
forming a first well region of a first doping type extending inward from a surface of the epitaxial layer and extending to a surface of the buried layer;
forming a second well region and a third well region of a second doping type extending from the surface of the epitaxial layer to the interior and extending to the surface of the buried layer, the second well region and the third well region being located on both sides of the first well region and separated from the first well region, respectively;
forming a fourth well region of a second doping type extending inward from a surface of the first well region and separated from the buried layer;
forming a first drift region and a second drift region of a first doping type extending from the surface of the first well region to the interior and separated from the buried layer, the first drift region and the second drift region being symmetrically distributed on both sides of the fourth well region and separated from the fourth well region;
forming a fifth well region of a first doping type in the first drift region and the second drift region, and forming a sixth well region of a first doping type in the second drift region;
forming a plurality of spaced field oxide layers located above and outside the epitaxial layer; and
forming a plurality of spaced injection regions with the field oxide layer as an interval, injection region located within well region and comprising first injection region and second injection region, the first injection region being of the first doping type, and the second injection region being of the second doping type, respectively,
wherein, the second injection region in the second well region, the second injection region in the third well region, and the first injection region in the fifth well region, and the first injection region in the sixth well region are connected to the cathode, and the first injection region in the fourth well region and the second injection region in the fourth well region are connected to the anode.
